(19) United States
(12) Patent Application Publication
(10) Pub. No.: US 2019/0067901 A1
(43) Pub. Date: Feb. 28, 2019

(54) INTEGRATED PACKAGE FOR LASER DRIVER AND LASER DIODE

(71) Applicant: Lumentum Operations LLC, Milpitas, CA (US)

(72) Inventors: Slava KHASSINE, Milpitas, CA (US); Lucas Morales, San Francisco, CA (US); Joseph Leigh, Milpitas, CA (US)

(21) Appl. No.: 16/102,096

(22) Filed: Aug. 13, 2018

Related U.S. Application Data
(60) Provisional application No. 62/552,156, filed on Aug. 30, 2017.

(51) Int. Cl. H01S 5/022; H01S 5/42; H01S 5/02; H01S 5/024

(52) U.S. Cl. CPC H01S 5/02228; H01S 5/02248; H01S 5/02288; H01S 5/02276; H01S 5/0201; H01S 5/02469; H01S 5/423

(57) ABSTRACT

An optical device may include a substrate and a plurality of optical components. he plurality of optical components may include a laser driver. The plurality of optical components may include a laser diode. The plurality of optical components may be encapsulated by an encapsulation material and the substrate.

### RELATED APPLICATION(S)

This application claims priority under 35 U.S.C. § 119 to U.S. Provisional Patent Application No. 62/552,156, filed on Aug. 30, 2017, the content of which is incorporated by reference herein in its entirety.

### TECHNICAL FIELD

The present disclosure relates to optical devices. More particularly, some aspects of the present disclosure relate to an integrated package for a laser driver and a laser diode using an overmolded encapsulation material.

### BACKGROUND

An optical device may include a laser diode to provide a beam. The laser diode may be coupled to a laser driver to drive the laser diode. The laser driver may provide a signal to control an optical output of the laser diode (e.g., a beam). For example, the laser driver may receive an input signal, and may generate a driver signal to drive the laser diode. Based on receiving the driver signal, the laser diode may provide a beam. For example, in an optical communications system, the laser driver may receive digital data, and may convert the digital data to a set of analog signals. In this case, the laser driver may provide the set of analog signals to the laser diode to cause the laser diode to provide a beam to convey the set of analog signals using an optical fiber. As another example, in an optical measurement system, the laser driver may receive an instruction to perform a measurement, and may provide a signal to the laser diode to cause the laser diode to provide a beam to perform the measurement.

The laser diode and the laser driver may be collocated on a single substrate. For example, the laser diode and the laser driver may be disposed onto a printed circuit board that provides an electrical connection between the laser diode and the laser driver, an electrical connection between the laser driver and another component, and/or the like. Environmental conditions, such as excessive heating and cooling, exposure to light, exposure to particulate matter, and/or the like may degrade performance of an optical device that includes a laser diode and a laser driver. As a result, the optical device may be enclosed in a hermetically sealed case to reduce an exposure to environmental conditions.

### SUMMARY

According to some possible implementations, an optical device may include a substrate and a plurality of optical components. he plurality of optical components may include a laser driver. The plurality of optical components may include a laser diode. The plurality of optical components may be encapsulated by an encapsulation material and the substrate.

According to some possible implementations, an optical device may include a die that is associated with a threshold thermal conductivity. The die may include a laser associated with a wavelength. The die may include a laser driver electrically connected to the laser. The die may include a silicone encapsulation material encapsulating the laser and the laser driver may be on the die.

According to some possible implementations, a method may include disposing a plurality of laser diodes and a corresponding plurality of laser drivers onto a substrate. The method may include disposing an encapsulation material onto the substrate to hermetically seal each laser diode, of the plurality of laser diodes, with a corresponding laser driver, of the corresponding plurality of laser drivers. The method may include dividing the substrate to form a plurality of optical devices. Each optical device, of the plurality of optical devices, may include at least one laser diode, of the plurality of laser diodes, and at least one laser driver, of the corresponding plurality of laser drivers encapsulated by a portion of the encapsulation material.

### BRIEF DESCRIPTION OF THE DRAWINGS

FIG. 1 is a diagram of an overview of an example implementation described herein;

FIG. 2 is a diagram of an integrated package for a laser driver and a laser diode described herein;

FIG. 3 is a diagram of an integrated package for a laser driver and a laser diode described herein; and

FIGS. 4A-4C are diagrams of integrated packages for a laser driver and a laser diode described herein.

### DETAILED DESCRIPTION

The following detailed description of example implementations refers to the accompanying drawings. The same reference numbers in different drawings may identify the same or similar elements.

A substrate may be provided to mount a laser diode and a laser driver to form an optical module, such as for an optical communications system, an optical measurement system, and/or the like. The substrate may electrically couple the laser diode and the laser driver to enable the laser driver to provide a signal to drive the laser diode. The substrate may electrically couple the laser driver to other circuitry, such as other circuitry on the substrate, other circuitry external to the substrate, and/or the like. For example, the substrate may enable a device to provide a signal to the laser driver to cause the laser driver to drive the laser diode. Exposure to environmental conditions, such as excessive heating and cooling, exposure to light, exposure to particulate matter, and/or the like may degrade performance of an optical device that includes a laser diode and a laser driver.

As a result, the optical device may be enclosed in a hermetically sealed case to reduce an exposure to environmental conditions. However, a hermetically sealed case for a laser driver and a laser diode may result in excessive cost and/or an excessively large form factor. Some implementations, described herein, may provide an integrated package for a laser driver and a laser diode. In this way, a form factor for an optical device may be reduced relative to providing a separate enclosure into which the optical device may be disposed. Moreover, a manufacturability of the optical device may be improved relative to providing a separate enclosure into which the optical device may be disposed.

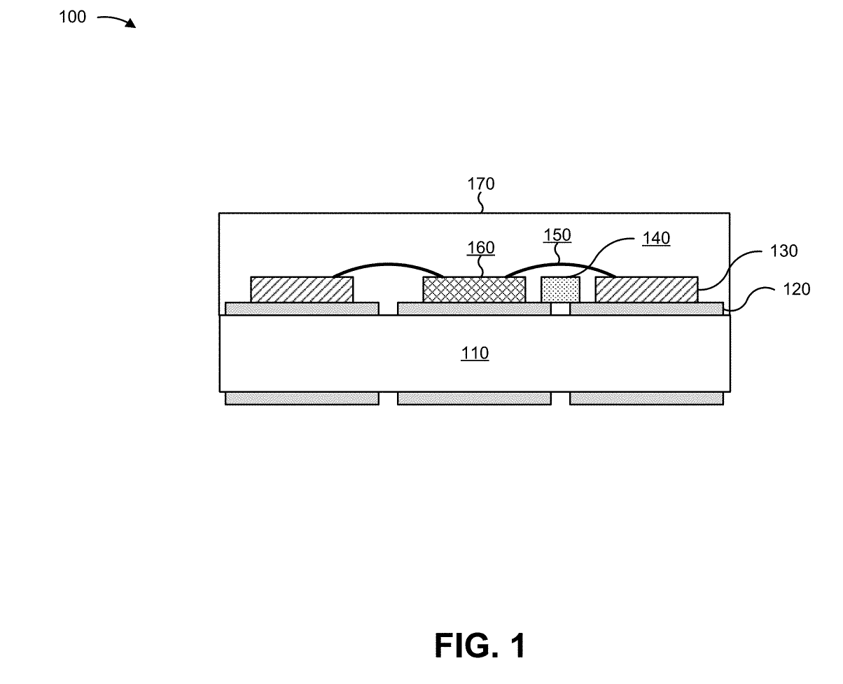

FIG. 1 is a diagram of an overview of an example implementation 100 described herein. FIG. 1 shows an example of an integrated package for a laser driver and a laser diode.

As shown in FIG. 1, example 100 includes a substrate 110 and a set of copper pads 120 disposed onto a top side of substrate 110 and a bottom side of substrate 110. Further, example 100 includes a set of capacitors 130, a laser driver 140, a set of wire bonds 150, a laser diode 160, and an encapsulation material 170.

In some implementations, substrate 110 may be manufactured from a particular material. For example, substrate 110 may be a material with greater than a threshold thermal conductivity, such as greater than 0.25 watts per meter Kelvin (W/m*K), greater than 0.5 W/m*K, greater than 0.75 W/m*K, greater than 1 W/m*K, and/or the like. In this way, substrate 110 may dissipate heat generated by, for example, laser driver 140, laser diode 160, and/or the like, which may enable a threshold level of peak optical power at a threshold current and/or a threshold ambient temperature. In some implementations, substrate 110 (e.g., a ceramic printed circuit board (PCB) instead of FR4 glass-reinforced epoxy laminate), may be associated with a threshold thermal conductivity to enable heat dissipation for laser diode 160, laser driver 140, and/or the like. In this way, a optical device of example implementation 100 may be used in connection with, for example, a sustained peak optical power at high current and high ambient temperature. For example, sustained peak optical power may involve an optical power of 100W being maintained for a relevant portion of the duration of an approximately 20 nanosecond pulse. Depending on how many emitters may be in the die and how those emitters may be connected together (e.g., in series, in parallel, combinations thereof), tens of amps of current may be required to maintain a sustained peak optical power. High ambient temperature may depend on the operating environment and may occur above 30° C. or up as high as 60° C.

In some implementations, substrate 110 may be an aluminum nitride (AlN) based material. For example, substrate 110 and copper pads 120 may form a copper-aluminum-nitride-copper (Cu—AlN—Cu) stack. In some implementations, substrate 110 and copper pads 120 may form a set of surface-mount technology (SMT) pads. For example, the set of SMT pads may be disposed on a bottom surface of substrate 110 (e.g., the set of SMT pads may be formed using copper pads 120 on the bottom surface of substrate 110). In this way, substrate 110 and copper pads 120 enable coupling (e.g., electrical coupling) to another component without a disruption of a hermetic seal provided by encapsulation material 170.

In some implementations, substrate 110 may include one or more interconnects on a top surface of substrate 110. In some implementations, the one or more interconnects on the top surface of substrate 110 may be positioned at a location of substrate 110 outside of encapsulation material 170. For example, encapsulation material may cover a portion of a surface area of substrate 110, and the one or more interconnects may be disposed on another portion of the surface area of substrate 110. Additionally, or alternatively, the one or more interconnects on the top surface of substrate 110 may be positioned within a boundary of encapsulation material 170. In this case, a connection to another component using the one or more interconnects may be disposed through encapsulation material 170 and/or encapsulation material 170 may be disposed around the connection to the other component. In some implementations, copper pads 120 may be plated onto substrate 110, deposited onto substrate 110, sputtered onto substrate 110, adhered to substrate 110, and/or the like.

In some implementations, driver circuitry, such as a set of capacitors 130, a laser driver 140, and/or the like may be disposed onto copper pads 120. For example, a first capacitor 130 may be disposed onto a first copper pad 120 on a first portion of substrate 110 and a second capacitor 130 may be disposed onto a second copper pad 120 on a second portion of substrate 110. Additionally, or alternatively, the laser driver 140 may be disposed onto both the first copper pad 120 and a third copper pad 120 (e.g., on a third portion of substrate 110) on which laser diode 160 is disposed. In this way, laser driver 140 may be electrically coupled to laser diode 160 to enable laser driver 140 to drive laser diode 160. Moreover, based on integrating laser diode 160 and laser driver 140 onto a common substrate, an inductance associated with laser diode 160 and laser driver 140 may be reduced relative to another configuration. In this way, use of laser diode 160, such as for time-of-flight (TOF) LIDAR, is enabled.

In some implementations, laser driver 140 may be a die component, such as a bare die component. For example, laser driver 140 may be a bare die mounted to substrate 110 and/or onto copper pads 120. In this case, laser driver 140 may couple to laser diode 160 via a set of wire bonds, such as using wire bonds 150. Additionally, or alternatively, laser driver 140 may be a discrete, packaged component mounted to substrate 110 and/or onto copper pads 120. In this case, laser driver 140 may couple to laser diode 160 via one or more electrical traces associated with copper pads 120. In some implementations, laser driver 140 may be another type of driver, such as an integrated circuit driver and/or the like. In some implementations, laser diode 160 may be a vertical-cavity surface-emitting laser (VCSEL) and/or the like.

In some implementations, encapsulation material 170 may be associated with a particular type of material. For example, encapsulation material 170 may be an epoxy-based material (e.g., a transparent epoxy) disposed onto substrate 110, laser driver 140, laser diode 160, and/or the like. In some implementations, encapsulation material 170 may be a silicone encapsulation material. For example, encapsulation material 170 may be silicone overmolded onto substrate 110, laser driver 140, laser diode 160.

In some implementations, encapsulation material 170 may include multiple materials. For example, a first encapsulation material 170, which may be non-transparent, may be disposed over, for example, laser driver 140, and a second encapsulation material 170, which may be transparent, may be disposed over laser diode 160 (e.g., in a direction of beam propagation of a beam that laser diode 160 is configured to provide). In this way, encapsulation material 170 may reduce an environmental exposure to components relative to an all-transparent encapsulation material, and may permit laser diode 160 to couple to another optical component external to encapsulation material 170.

In some implementations, encapsulation material 170 may be a single, transparent encapsulation material 170 overmolded over substrate 110, laser driver 140, laser diode 160, and/or the like, thereby reducing a quantity of manufacturing steps relative to using multiple materials for encapsulation material 170. In some implementations, encapsulation material 170 may be associated with a threshold transmittance at a wavelength of laser diode 160, such as greater than 50%, greater than 75%, greater than 90%, greater than 95%, greater than 97%, greater than 98%, greater than 99%, and/or the like. In some implementations, encapsulation material 170 may be associated with a threshold temperature resistance (e.g., an ability to withstand deformation or changes to properties of the encapsulation material 170 at high temperatures such as up to 200° C.), thereby protecting or insulating laser driver 140 and laser diode 160. For certain applications (e.g. outdoor and automotive), high temperature resistance and UV light resistance can be important features for encapsulation material 170. For example, silicone provides high temperature resistance, UV light resistance and high transparency at the laser diode wavelength. Additionally, or alternatively, encapsulation material 170 may be associated with improving vibrational tolerance, impact tolerance, and/or the like for laser driver 140, laser diode 160, and/or the like, thereby improving a durability of laser driver 140, laser diode 160, and/or the like relative to a non-encapsulated optical device. In some implementations, encapsulation material 170 may block ultra-violet (UV) light, thereby improving a durability of laser driver 140, laser diode 160, and/or the like. In some implementations, encapsulation material 170 may be associated with a threshold refractive index (e.g. 1.39 to 1.6).

In some implementations, encapsulation material 170 may provide a hermetic seal. For example, encapsulation material 170 may hermetically seal laser driver 140, laser diode 160, and/or the like with substrate 110 to isolate laser driver 140, laser diode 160, and/or the like from an external environment, such as from humidity, dust, corrosive gasses, vibration, temperature, and/or the like. In this way, encapsulation material 170 reduces an effect of environmental conditions on laser driver 140, laser diode 160, and/or the like. In some implementations, encapsulation material 170 may hermetically seal a top surface of substrate 110, thereby providing environmental protection to electrical traces on the top surface of substrate 110, copper pads 120, a material of substrate 110, and/or the like.

As indicated above, FIG. 1 is provided merely as an example. Other examples are possible and may differ from what was described with regard to FIG. 1.

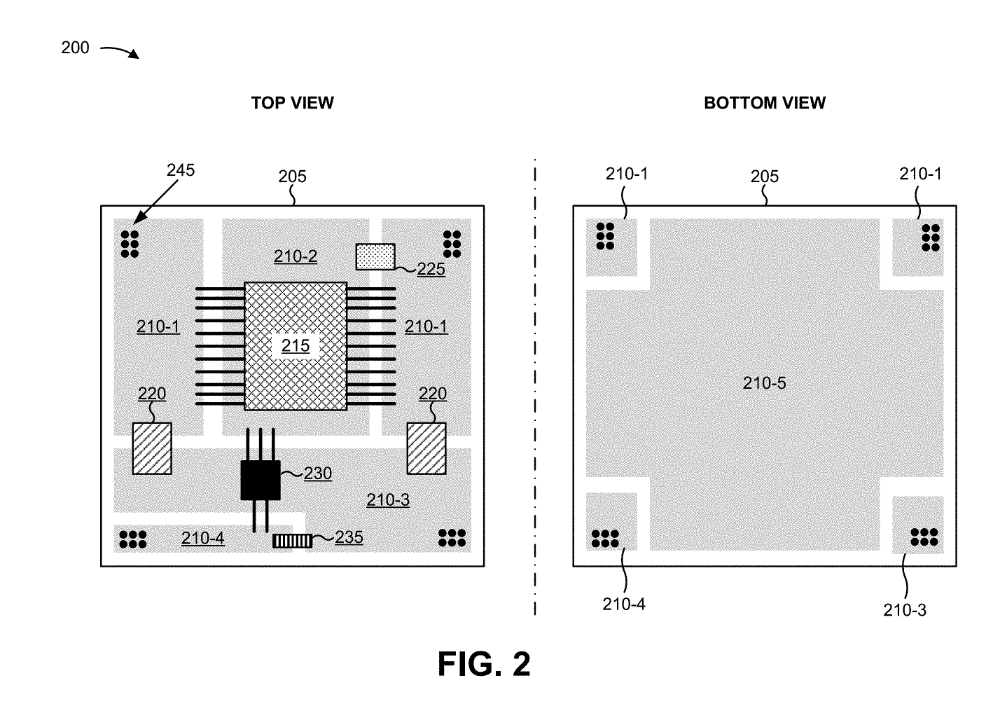

FIG. 2 is a diagram of an optical device 200 that includes an integrated package for a laser diode and a laser driver, as described herein.

As shown in FIG. 2, optical device 200 includes a substrate 205, a set of copper pads 210-1 through 210-5, a laser diode 215, a set of capacitors 220, a reverse diode 225, a laser driver 230, a resistor 235, and multiple sets of vias 245. In some implementations, copper pads 210 may include multiple different types of copper pads. For example, a set of copper pads 210-1, which may be disposed on both a top surface and a bottom surface of substrate 205, may be anode pads. Similarly, copper pad 210-2 may be a cathode pad disposed on the top surface of substrate 205. In this case, reverse diode 225 may bridge a copper pad 210-1 and copper pad 210-2. In this way, substrate 205 and copper pads 210 provide a path for electrical current for laser diode 215. In some implementations, copper pad 210-3 may be a source pad disposed on the top surface and the bottom surface of substrate 205. In this case, capacitors 220 may bridge copper pad 210-3 and copper pads 210-1, and resistor 235 may bridge copper pad 210-3 and copper pad 210-4, which may be a source pad disposed on the top surface and the bottom surface of substrate 205. In some implementations, copper pad 210-3, which may be disposed on the bottom surface of substrate 205, may be a thermal pad to provide a thermal functionality, such as a heat sink functionality for optical device 200. In some implementations, vias 245 may extend from copper pads 210 on a top surface of substrate 205 to copper pads 210 on a bottom surface of substrate 205.

In some implementations, a bottom surface of substrate 205 and copper pads 210 may form a set of surface-mount technology (SMT) pads. For example, optical device 200 may be configured to mount to another optical device or optical system, such as for an optical measurement system (e.g., a LIDAR system), an optical communications system, and/or the like. In this way, optical device 200 may be coupled to another optical device without an interruption to an encapsulation material disposed onto a top surface of substrate 205, copper pads 210, and/or optical components mounted thereto. Additionally, or alternatively, a connection may be disposed within the encapsulation material. For example, a wire bond may couple to a component of optical device 200, may pass through the encapsulation material, and may enable optical device 200 to electrically couple to another optical device external to the encapsulation material. Similarly, a waveguide or another type of optical path may extend from, for example, laser diode 215 through the encapsulation material to optically couple optical device 200 to another optical device.

In some implementations, one or more components of optical device 200 may be associated with a higher threshold thermal conductivity than provided in prior optical devices. For example, substrate 205 (e.g. ceramic PCB instead of FR4), copper pads 210, and/or the like may be associated with a threshold thermal conductivity to enable heat dissipation for laser diode 215, laser driver 230, and/or the like. In this way, optical device 200 may be used in connection with, for example, maintaining a threshold sustained peak optical power (e.g. high sustained peak optical power), a threshold current (e.g. high current), a threshold ambient temperature (e.g. a high ambient temperature). For example, substrate 205 may be associated with a threshold thermal conductivity to enable heat dissipation for laser diode 215, laser driver 230, and/or the like. In this way, optical device 200 may be used in connection with, for example, a sustained peak optical power at high current and high ambient temperature. For example, sustained peak optical power may involve an optical power of 100W being maintained for a relevant portion of the duration of an approximately 20 nanosecond pulse. Depending on how many emitters may be in the die and how those emitters may be connected together (e.g. in series, in parallel, combinations thereof), tens of amps of current may be required to maintain a sustained peak optical power. High ambient temperature may depend on the operating environment and may occur above 30° C. or up as high as 60° C.

In some implementations, optical device 200 may include one or more other components (e.g., encapsulated by the encapsulation material). For example, optical device 200 may include an electrostatic discharge (ESD) protection component, such as a transient-voltage-suppression (TVS) diode and/or the like. Additionally, or alternatively, optical device 200 may include a measurement component, such as a thermistor (e.g., to monitor a temperature associated with the laser diode). In this case, thermistor may couple to a thermo-electric cooler to maintain a temperature of laser diode 215, to laser driver 230 to control laser diode 215, and/or the like. Similarly, optical device 200 may include an optical component, such as a diffuser, a diffractive optical element (DOE), a lens (e.g., a collimating lens, a microlens, and/or the like), and/or the like. In some implementations, optical device 200 may include a metal-oxide-semiconductor field-effect transistor (MOSFET), an enhanced gallium nitride field-effect transistor (eGAN FET), and/or the like. In some implementations, one or more of the components of optical device 200 may be disposed outside of the encapsulation material. For example, the lens may be mounted onto the encapsulation material, and may couple to laser diode 215 via the encapsulation material.

Although some implementations, described herein, are described in terms of a beam transmitter, implementations described herein may be used for an integrated package for a beam receiver (e.g., a photodiode coupled to a photodiode driver, an optical transceiver, and/or the like). For example, substrate 205 may include a photodetector to enable a LIDAR sensor (e.g., a LIDAR transmitter and a LIDAR receiver integrated into a single package). In some implementations, the encapsulation material may filter light. For example, in a LIDAR sensor use case, the encapsulation material may filter ambient light (e.g., indoor ambient light, outdoor ambient light, sunlight, artificial light, and/or the like) such that a photodiode or image sensor of the LIDAR sensor receives light for a particular spectrum associated with LIDAR receiving, thereby improving signal to noise ratio relative to a LIDAR sensor that does not include an encapsulation material to filter, for example, ambient light. In this case, the encapsulation material may be overmolded silicone configured to be transparent in the particular spectrum associated with LIDAR receiving.

In some implementations, optical device 200 may be formed using a depositing procedure. For example, a pick and place technique may be used to dispose laser diode 215 and laser driver 230 onto substrate 205. In this case, the encapsulation material may be disposed onto laser diode 215, laser driver 230, substrate 205, and/or the like to form optical device 200, such as by overmolding the encapsulation material, depositing the encapsulation material, sputtering the encapsulation material, and/or the like. Additionally, or alternatively, multiple laser diodes 215 and laser drivers 230 may be disposed onto substrate 205. In this case, after disposing the encapsulation material (and/or one or more other optical layers, such as a film, a lens, a grating, and/or the like) onto laser diode 215, laser driver 230, substrate 205, and/or the like, substrate 205 may be divided (e.g., diced) to form multiple optical devices 200 (e.g., each with a portion of substrate 205, a laser diode 215, a laser driver 230, and a portion of the encapsulation material). In this way, an amount of time to manufacture multiple optical devices 200 may be reduced relative to manufacturing each optical device 200 separately.

As indicated above, FIG. 2 is provided merely as an example. Other examples are possible and may differ from what was described with regard to FIG. 2.

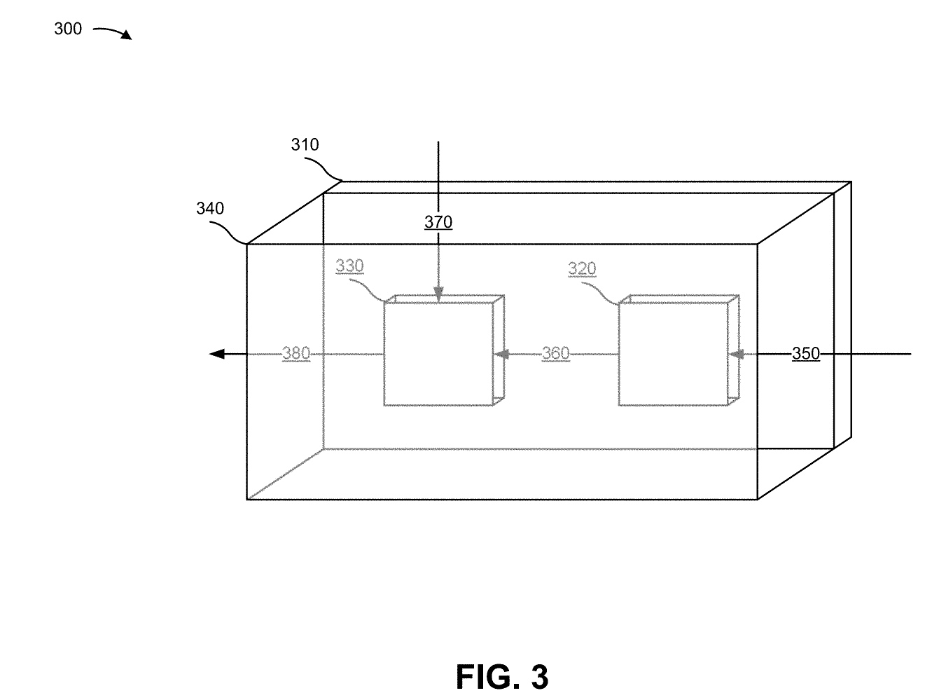

FIG. 3 is a diagram of an optical device 300 that includes an integrated package for a laser diode and a laser driver, as described herein.

As shown in FIG. 3, optical device 300 includes a substrate 310, driver circuitry 320 (e.g., a laser driver, a capacitor, a thermistor, and/or the like), a laser diode 330, and an encapsulation material 340. As shown by reference number 350, driver circuitry 320 may receive an input signal from, for example, a device external to optical device 300. For example, driver circuitry 320 may receive the input signal from a device coupled to optical device 300 via a set of SMT pads of optical device 300. Additionally, or alternatively, driver circuitry 320 may receive the input from a connection through encapsulation material 340. Additionally, or alternatively, driver circuitry 320 may include an antenna and may receive the input via an air interface. In some implementations, the input may include information for communication. For example, driver circuitry 320 may receive a digital signal for transmission using a beam of an optical communication system. Additionally, or alternatively, the input may include an instruction. For example, driver circuitry 320 may receive an instruction to cause laser diode 330 to provide a beam for a measurement, such as in an optical measurement system.

As further shown in FIG. 3, and by reference number 360, driver circuitry 320 may drive laser diode 330. For example, driver circuitry 320 may provide an analog signal to laser diode 330 to cause laser diode 330 to provide a beam. Additionally, or alternatively, driver circuitry 320 may provide an instruction to cause laser diode 330 to provide a beam. As shown by reference number 370, laser diode 330 may receive other input to enable laser diode 330 to provide a beam. For example, laser diode 330 may receive feedback information identifying a characteristic of a beam to enable laser diode 330 to control the beam. As shown by reference number 380, laser diode 330 may provide the beam. For example, laser diode 330 may provide the beam for communication, for measurement, and/or the like. In some implementations, laser diode 330 may provide the beam via a waveguide. For example, laser diode 330 may be coupled to a waveguide, and may provide the beam via the waveguide. In this case, the waveguide may be disposed through encapsulation material 340. Additionally, or alternatively, the waveguide may be formed by encapsulation material 340 and coupled to, for example, another waveguide external to encapsulation material 340. In some implementations, laser diode 330 may emit a beam from an edge surface. For example, laser diode 330 may be an edge emitter. Additionally, or alternatively, laser diode 330 may be a vertical-cavity surface-emitting laser (VCSEL).

As indicated above, FIG. 3 is provided merely as an example. Other examples are possible and may differ from what was described with regard to FIG. 3.

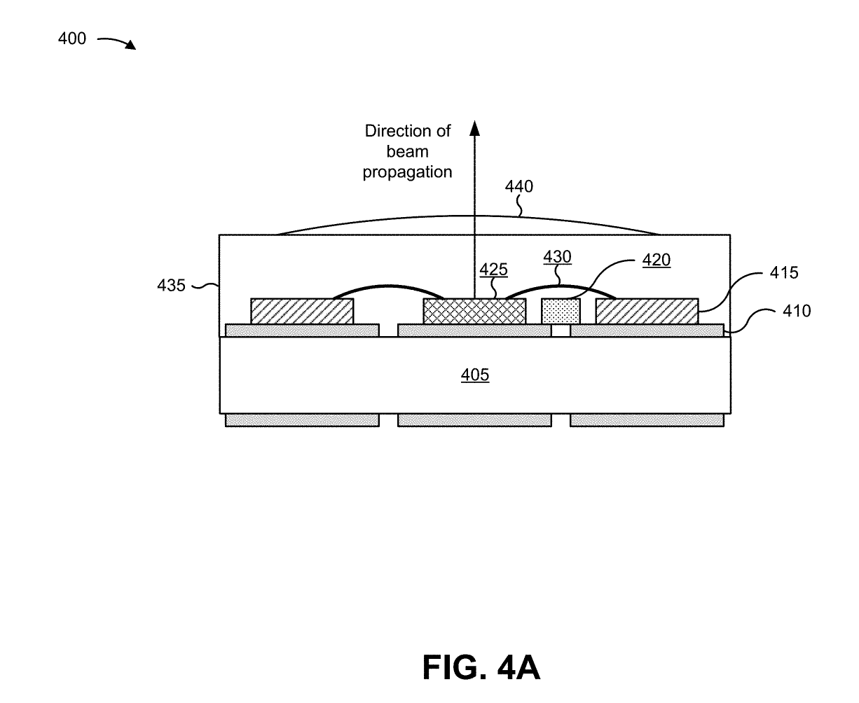

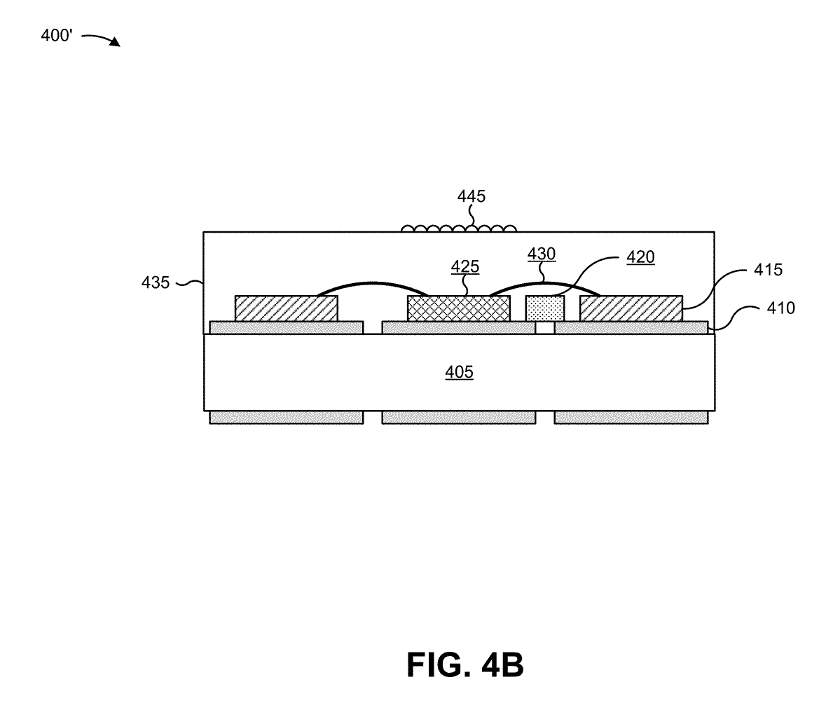

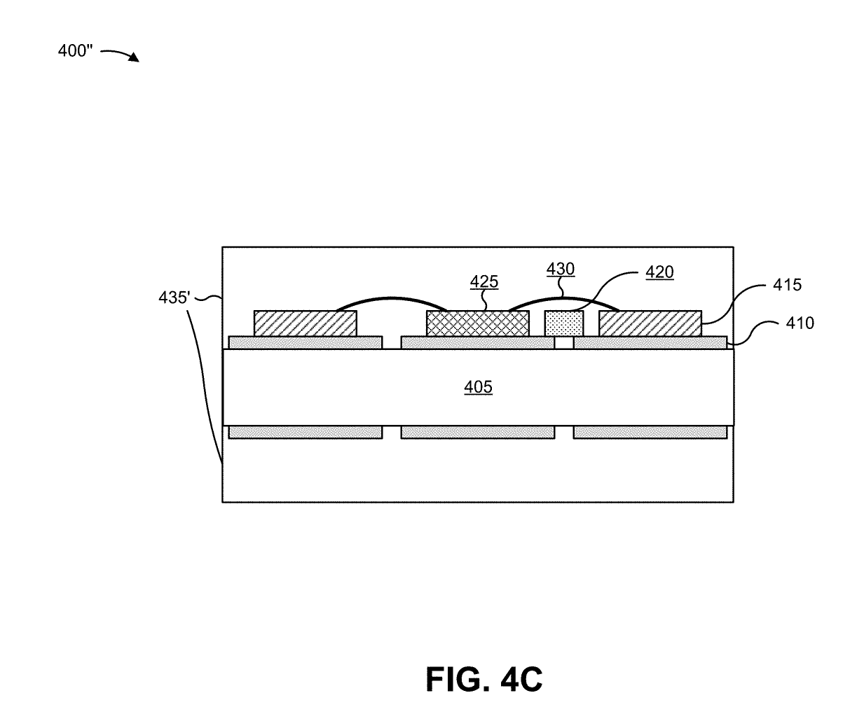

FIGS. 4A-4C are diagrams of example implementations 400/400′/400″ of an integrated package for a laser diode and a laser driver, as described herein.

As shown in FIG. 4A, optical device 400 includes a substrate 405, a set of copper pads 410, a set of capacitors 415, a driver 420, a laser diode 425, a set of wire bonds 430, and an encapsulation material 435. In some implementations, optical device 400 may include a lens 440 aligned to laser diode 425 in a direction of beam propagation. In this way, optical device 400 may alter a beam provided by laser diode 425, such as to direct the beam, focus the beam, diffuse the beam, collimate the beam, and/or the like. In some implementations, lens 440 may be integrated into encapsulation material 435. For example, lens 440 may be included in encapsulation material 435. Additionally, or alternatively, lens 440 may be formed from encapsulation material 435. Additionally, or alternatively, lens 440 may be mounted onto encapsulation material 435. In some implementations, another optical element may be disposed onto, disposed into, or formed from encapsulation material 435, such as a film, a coating, a grating, and/or the like.

As shown in FIG. 4B, optical device 400′ includes a set of microlenses 445 rather than a single lens 440. For example, when laser diode 425 is an array of laser diodes forming a laser array and providing multiple beams, optical device 400′ may include multiple microlenses 445 aligned to multiple laser diodes 425 of the laser diode array 425. In this way, optical device 400′ may alter (e.g., direct, focus, collimate, and/or the like) multiple beams from a laser diode array 425.

As shown in FIG. 4C, optical device 400″ includes an encapsulation material 435′ rather than encapsulation material 435. In this case, encapsulation material 435′ is disposed onto a top surface and a bottom surface of substrate 405 and/or components mounted thereto. In some implementations, encapsulation material 435″ may encapsulate one or more side surfaces of substrate 405. In this way, encapsulation material 435′ provides a hermetic seal for multiple surfaces of substrate 405 and/or components mounted to the multiple surfaces of substrate 405.

As indicated above, FIGS. 4A-4C are provided merely as examples. Other examples are possible and may differ from what was described with regard to FIGS. 4A-4C.

In this way, an encapsulation material, such as overmolded silicone, may be disposed onto a substrate and/or a set of components (e.g., a laser driver, a laser diode, and/or the like), thereby providing protection for the substrate and/or the set of components, alignment to a lens for a laser diode, and/or the like.

The foregoing disclosure provides illustration and description, but is not intended to be exhaustive or to limit the implementations to the precise form disclosed. Modifications and variations are possible in light of the above disclosure or may be acquired from practice of the implementations.

Some implementations are described herein in connection with thresholds. As used herein, satisfying a threshold may refer to a value being greater than the threshold, more than the threshold, higher than the threshold, greater than or equal to the threshold, less than the threshold, fewer than the threshold, lower than the threshold, less than or equal to the threshold, equal to the threshold, or the like.

Even though particular combinations of features are recited in the claims and/or disclosed in the specification, these combinations are not intended to limit the disclosure of possible implementations. In fact, many of these features may be combined in ways not specifically recited in the claims and/or disclosed in the specification. Although each dependent claim listed below may directly depend on only one claim, the disclosure of possible implementations includes each dependent claim in combination with every other claim in the claim set.

No element, act, or instruction used herein should be construed as critical or essential unless explicitly described as such. Also, as used herein, the articles “a” and “an” are intended to include one or more items, and may be used interchangeably with “one or more.” Furthermore, as used herein, the term “set” is intended to include one or more items (e.g., related items, unrelated items, a combination of related and unrelated items, etc.), and may be used interchangeably with “one or more.” Where only one item is intended, the term “one” or similar language is used. Also, as used herein, the terms “has,” “have,” “having,” or the like are intended to be open-ended terms. Further, the phrase “based on” is intended to mean “based, at least in part, on” unless explicitly stated otherwise.

What is claimed is:

1. An optical device, comprising:
a substrate; and
a plurality of optical components,
wherein the plurality of optical components includes a laser driver,
wherein the plurality of optical components includes a laser diode,
wherein the plurality of optical components is encapsulated by an encapsulation material and the substrate.

2. The optical device of claim 1, wherein at least one component, not included in the plurality of optical components, is partially encapsulated by the encapsulation material.

3. The optical device of claim 1, wherein the substrate is associated with greater than a threshold thermal conductivity.

4. The optical device of claim 1, further comprising:
an interconnect to couple the laser driver to the laser diode.

5. The optical device of claim 1, wherein the encapsulation material is an epoxy.

6. The optical device of claim 1, wherein at least a portion of the encapsulation material is transparent at a wavelength of the laser diode.

7. The optical device of claim 1, wherein the encapsulation material is molded over driver circuitry associated with the plurality of optical components.

8. An optical device, comprising:
a die that is associated with a threshold thermal conductivity,
the die including:
a laser associated with a wavelength;
a laser driver electrically connected to the laser; and
a silicone encapsulation material encapsulating the laser and the laser driver on the die.

9. The optical device of claim 8, wherein the silicone encapsulation material has a threshold transmittance at the wavelength, a threshold temperature resistance, and a threshold refractive index.

10. The optical device of claim 8, further comprising:
a top surface interconnect disposed within the silicone encapsulation material to couple the laser driver to another component outside the silicone encapsulation material.

11. The optical device of claim 8, further comprising:
at least one of a photodetector, an electrostatic discharge protection component, a capacitor, a reverse diode, a resistor, a wire bond, a thermistor, a diffuser, a diffractive optical element, or a lens.

12. The optical device of claim 8, wherein the silicone encapsulation material isolates the laser and the laser driver from an external environment.

13. The optical device of claim 8, wherein the optical device includes a metal-oxide-semiconductor field-effect transistor (MOSFET) or an enhanced gallium nitride field-effect transistor (eGaN FET).

14. The optical device of claim 8, wherein the laser is configured to optically couple to another optical device external to the optical device.

15. The optical device of claim 8, further comprising:
a lens aligned to the laser.

16. The optical device of claim 8, further comprising:
a plurality of microlenses aligned to the laser.

17. The optical device of claim 8, wherein the laser is a laser array.

18. A method, comprising:
disposing a plurality of laser diodes and a corresponding plurality of laser drivers onto a substrate;
disposing an encapsulation material onto the substrate to hermetically seal each laser diode, of the plurality of laser diodes, with a corresponding laser driver, of the corresponding plurality of laser drivers; and
dividing the substrate to form a plurality of optical devices,
wherein each optical device, of the plurality of optical devices, includes at least one laser diode, of the plurality of laser diodes, and at least one laser driver, of the corresponding plurality of laser drivers encapsulated by a portion of the encapsulation material.

19. The method of claim 18, further comprising:
depositing, before dividing the substrate, an optical layer onto the encapsulation material; and
wherein dividing the substrate comprises:
dividing the optical layer such that each optical device, of the plurality of optical devices, includes a portion of the optical layer.

20. The method of claim 18, wherein the disposing the encapsulation material comprises at least one of:
overmolding the encapsulation material,
depositing the encapsulation material, or
sputtering the encapsulation material.
